(19) United States
(12) Patent Application Publication
(10) Pub. No.: US 2008/0316698 A1
(43) Pub. Date: Dec. 25, 2008

(54) Damping structure for electronic devices

(75) Inventors: Fun-Son Yeh, Taipei (TW); Brian Chang, Taipei (TW)

Correspondence Address: Joe McKinney Muncy, PO Box 1364, Fairfax, VA, 22038-1364, US

(73) Assignee: SHUTTLE INC.

(21) Appl. No.: 11/819,112

(22) Filed: Jun. 25, 2007

(51) Int. Cl. H05K 7/12

(52) U.S. Cl. 361/685; 361/807

(57) ABSTRACT

A damping structure for electronic devices has a holding rack mounted onto a chassis to hold an electronic device. The holding rack has two ends extended towards the chassis to form respectively a step portion and a first coupling section extended from the step portion. The holding rack has two other ends extended sideward to form second coupling sections to form a holding space for the electronic device. There are damping assemblies interposed between the holding rack and the chassis, and between the holding rack and the electronic device. The damping assemblies are independent and can provide elastic damping forces. Thus a desired damping effect can be provided for the electronic device to maintain regular operation

### FIELD OF THE INVENTION

The present invention relates to a damping structure for electronic devices and particularly to a. damping structure for holding an electronic device such as a storage device like hard disk drive or optical disk drive on a chassis (of a computer or portable external case) to provide optimal damping effect to facilitate regular operation of the electronic device.

### BACKGROUND OF THE INVENTION

These days people increasingly rely on computers to do their work and daily chores. Hence the computer becomes a necessary and indispensable technology product for many people. Advances of technology and growing demands of consumers have accelerated constant innovation of computer related products. The computer and its accessories can be upgraded according to user's requirement. To accommodate all sorts of data and software, the required space also increases. As a result the demand for hard disk also is greater.

Hard disk has many advantages such as higher storage density, greater capacity, lower cost and faster storing speed. Thus it becomes the mainstream of storage systems. As the hard disk is less expensive and has a greater capacity, it is widely used in notebook computers or other types of mobile electronic devices. But the hard disk has a big drawback, namely it is easily affected by shaking or instantaneous impact when in use, and could result in damage of the read/write head caused by impact with the disk platter. The tracks of the hard disk also could be damaged. In serious situations important data stored in the hard disk could be not recoverable. This is a big issue in the industry remained to be overcome.

To solve the aforesaid problems, R.O.C. patent No. M294728, entitled “Damping structure for hard disk of notebook computers” discloses a technique which mainly includes a hard disk container consisting of a chest and a lid. The chest has an opening at one end to connect the hard disk with a signal transmission flat cable and a power cord, and a hard disk drive held in the hard disk container. The chest of the hard disk container has elastic elements attached to the bottom and the periphery thereof. The lid also has elastic elements at one side facing the chest. When the hard disk drive is held in the chest, and the chest is covered by the lid, the elastic elements encase the hard disk drive. While such a structure can provide damping effect, it still has problems, notably:
1. With the hard disk encased by the elastic elements, it cannot disperse heat during operation. Hence the operation temperature of the hard disk is higher, the performance is affected.
2. The conventional technique mentioned above requires a great deal of elements. As a result, production cost is higher, and user installation time is longer.

### SUMMARY OF THE INVENTION

The primary object of the present invention is to solve the aforesaid disadvantages. The invention provides a damping structure that adopts an open space design. It has a holding rack mounted onto a chassis to hold an electronic device. The holding rack has two ends extended towards the chassis to form respectively a step portion and a first coupling section extended further from the step portion. The holding rack has two other ends extended sideward to form second coupling sections which form a holding space for the electronic device. There are damping assemblies interposed between the holding rack and the chassis, and between the holding rack and the electronic device. The damping assemblies are independent and can provide elastic damping forces. Thus a desired damping effect can be provided for the electronic device to maintain regular operation.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of the invention.

FIG. 2 is an exploded view of the invention.

FIG. 3 is a sectional view of a first damping assembly of the invention.

FIG. 4 is a sectional view of a second damping assembly of the invention.

### DETAILED DESCRIPTION OF THE PREFERRED EMBODIMENT

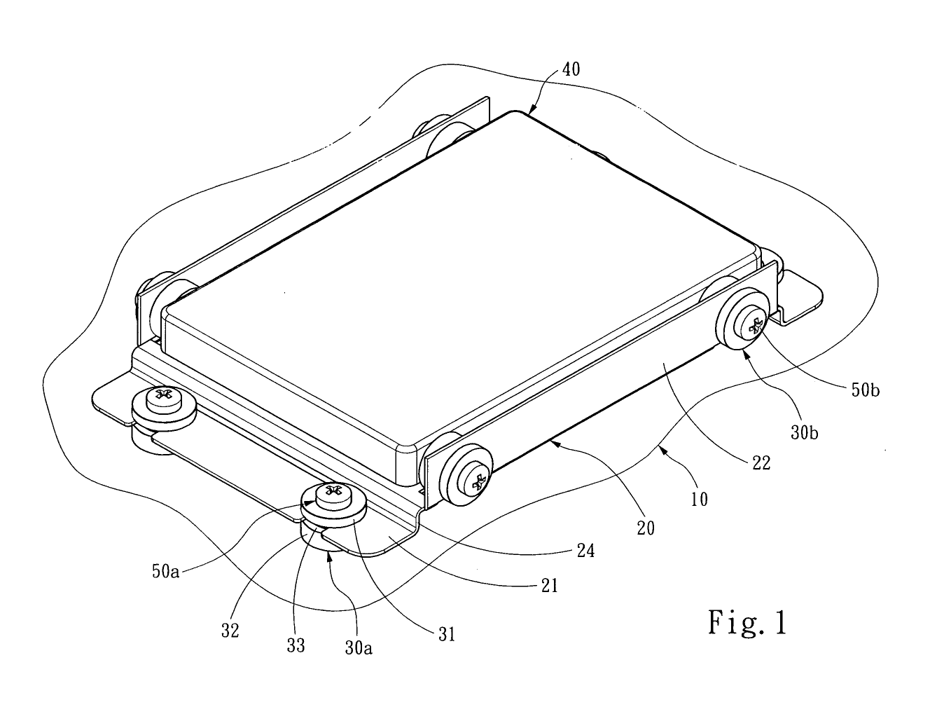

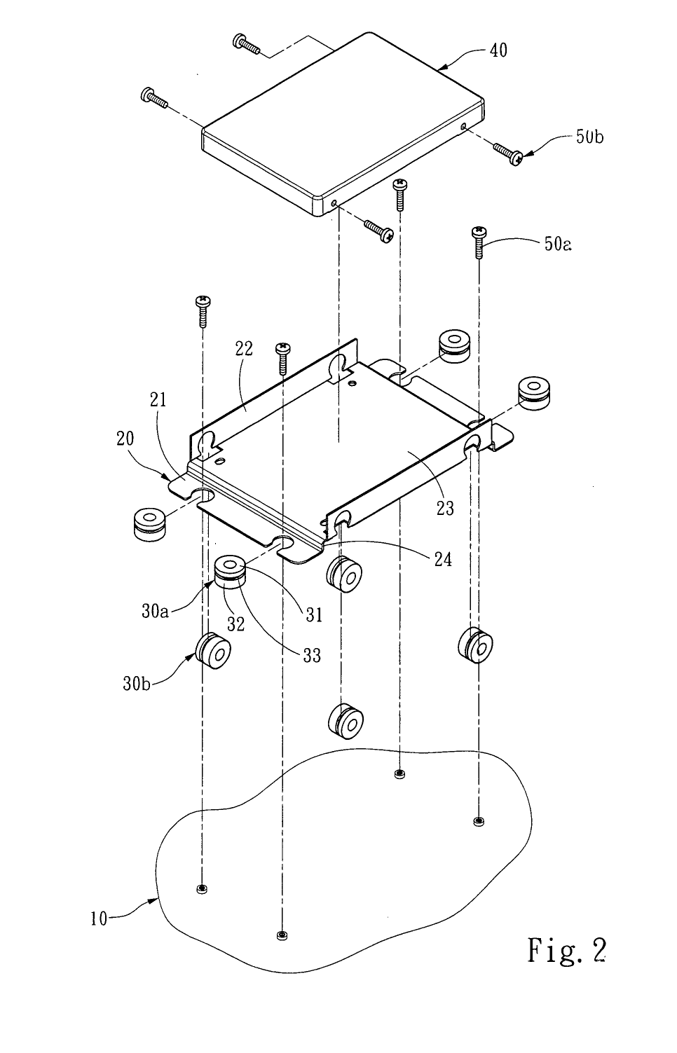

Please refer to FIGS. 1 and 2, the damping structure according to the invention is installed on a chassis 10 to hold at least one electronic device 40. It mainly includes a holding rack 20 which has a frame 23. The frame 23 has two ends extended sideward towards the chassis 10 to form respectively a step portion 24. The step portion 24 has one end extended horizontally relative to the chassis 10 to form a first coupling section 21. The frame 23 has another two ends extended in a direction opposite to the step portion 24 to form respectively a second coupling section 22. The second coupling section 22 and the frame 23 form a holding space for the electronic device 40. The invention is interposed between the holding rack 20 and the chassis 10, and the holding rack 20 and the electronic device 40, and includes a first damping assembly and a second damping assembly that are independent to provide elastic damping forces. The first damping assembly is located between the first coupling section 21 and the chassis 10, and includes a first buffer 30a interposed between the first coupling section 21 and the chassis 10 to provide the elastic damping forces and a first fastening element 50a running through the first buffer 30a to fasten the first coupling section 21 and the chassis 10. Similarly, the second damping assembly is located between the second coupling section 22 and the electronic device 40, and includes a second buffer 30b interposed between the second coupling section 22 and the electronic device 40 to provide the elastic damping forces and a second fastening element 50b running through the second buffer 30b to fasten the second coupling section 22 and the electronic device 40. The electronic device 40 is not limited to a storage device such as a hard disk drive or optical disk drive. The chassis 10 can be, but not limited to, a side board of a computer or a bottom board of an external case of a portable electronic device 40.

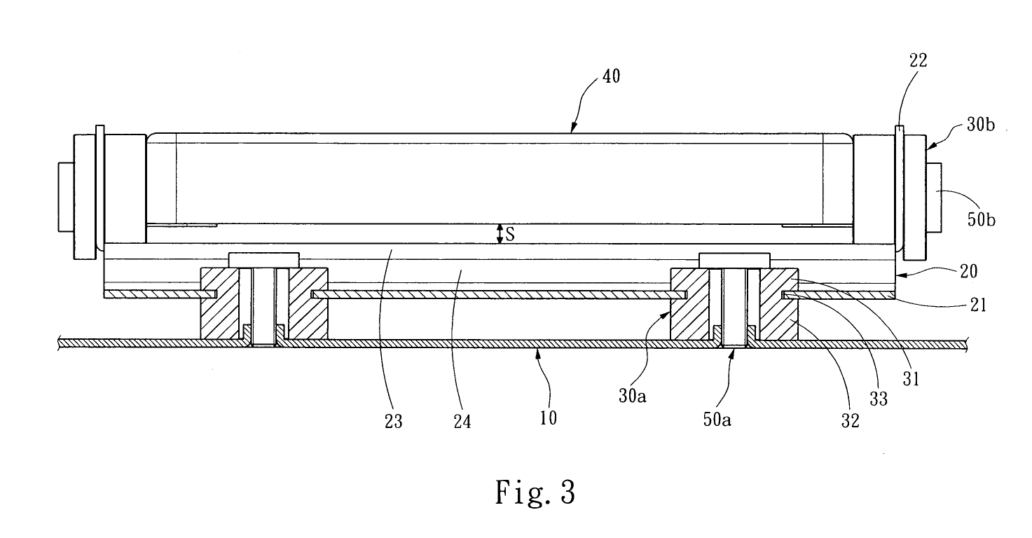

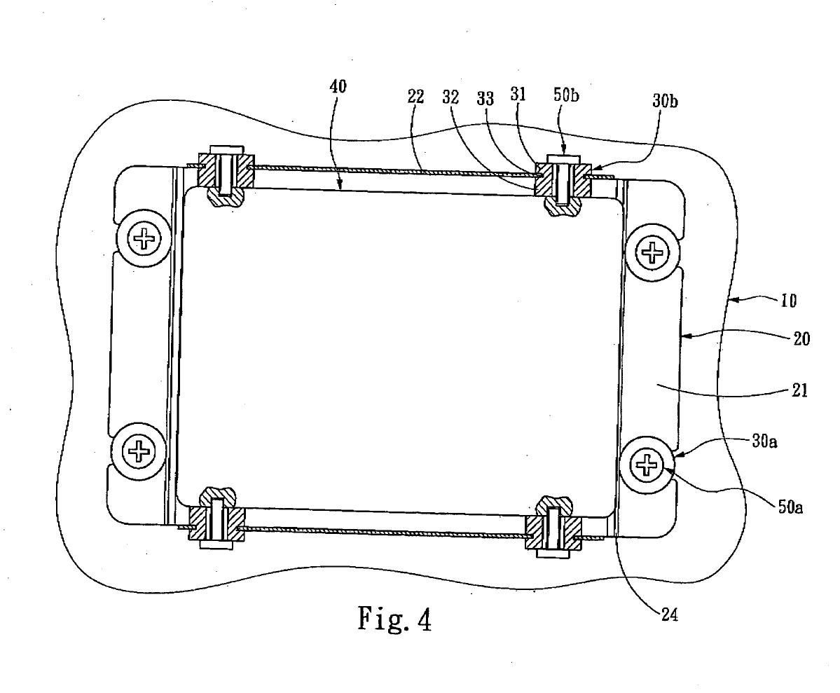

Refer to FIGS. 3 and 4 for an embodiment of the invention. The first buffer 30a of the first damping assembly includes a lower portion 32 located between the first coupling section 21 and the chassis 10, a upper portion 31 located between the first fastening element 50a and the first coupling section 21, and a middle portion 33 wedged by the first coupling section 21. Similarly, the second buffer 30b of the second damping assembly includes a lower portion 32 located between the second coupling section 22 and the electronic device 40, an upper portion 31 located between the second fastening element 50b and the second coupling section 22, and a middle portion 33 wedged by the second coupling section 22. By means of the upper portion 31 and lower portion 32 of the first and second buffers 30a and 30b, the holding rack 20 and the chassis 10, and the holding rack 20 and the electronic device 40, are in contact with only the first and second buffers 30a and 30b that provide elastic damping forces. Hence even if any improper external force occur to the chassis 10, the first and second buffers 30a and 30b can eliminate transmission of the external force to keep the electronic device 40 from receiving impact of the external force. Therefore the electronic device 40 can maintain regular operation.

Moreover, the frame 23 of the holding rack 20 may be a plane holding board to hold the electronic device 40, or through the second damping assembly and the second coupling section 22 to make the electronic device 40 to be spaced from the frame 23 at an interval S (referring to FIG. 3) without direct contact. As a result, transmission of the external force to the electronic device 40 can be further reduced to enhance operational reliability of the electronic device 40.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A damping structure for electronic devices mounted onto a chassis to hold at least one electronic device, comprising:
a holding rack having a frame which has two ends extended sideward towards the chassis to form respectively a step portion, the step portion having one end extended horizontally relative to the chassis to form a first coupling section, the frame having another two ends extended in a direction opposite to the step portion to form respectively a second coupling section, the second coupling section and the frame forming a holding space for the electronic device;
at least one first damping assembly which is located between the first coupling section and the chassis, and includes a first buffer interposed between the first coupling section and the chassis to provide an elastic damping force and a first fastening element running through the first buffer to fasten the first coupling section and the chassis; and
at least one second damping assembly which is located between the section coupling section and the electronic device, and includes a second buffer interposed between the second coupling section and the electronic device to provide an elastic damping force and a second fastening element running through the second buffer to fasten the second coupling section and the electronic device.

2. The damping structure of claim 1, wherein the first damping assembly includes a lower portion located between the first coupling section and the chassis, an upper portion located between the first fastening element and the first coupling section, and a middle portion wedged by the first coupling section.

3. The damping structure of claim 1, wherein the second damping assembly includes a lower portion located between the second coupling section and the electronic device, an upper portion located between the second fastening element and the second coupling section, and a middle portion wedged by the second coupling section.

4. The damping structure of claim 1, wherein the second damping assembly is installed on the second coupling section by forming a space between the electronic device and the frame so that they are not in contact with each other.

5. The damping structure of claim 1, wherein the chassis is a plane holding board to hold the electronic device.

6. The damping structure of claim 1, wherein the electronic device is a hard disk drive.

7. The damping structure of claim 1, wherein the electronic device is an optical disk drive.

8. The damping structure of claim 1, wherein the chassis is a side board of a computer.

9. The damping structure of claim 1, wherein the chassis is a bottom board of an external chest of a portable electronic device.
